(19) United States
(12) Patent Application Publication
(10) Pub. No.: US 2009/0068763 A1
(43) Pub. Date: Mar. 12, 2009

(54) METHOD FOR MANUFACTURING SEMICONDUCTOR DEVICE AND ITS MANUFACTURING METHOD

(75) Inventor: Takafumi NODA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/172,597

(22) Filed: Jul. 14, 2008

(30) Foreign Application Priority Data
Sep. 10, 2007 (JP) 2007-233877

(51) Int. Cl. H01L 21/00

(52) U.S. Cl. 438/3; 257/E21.001

(57) ABSTRACT

A method for manufacturing a semiconductor device includes the steps of: forming a ferroelectric capacitor having a first electrode, a ferroelectric film and a second electrode successively laminated on a base substrate; forming a first interlayer dielectric film that covers the ferroelectric capacitor and the base substrate; forming a material film for a second interlayer dielectric film covering the first interlayer dielectric film; exposing the first interlayer dielectric film located on the ferroelectric capacitor by polishing an upper surface side of the material film for the second interlayer dielectric film by a CMP method; forming a contact hole that penetrates the first interlayer dielectric film and exposes the second electrode, after the step of exposing the first interlayer dielectric film; and forming in the contact hole a plug conductive section that conductively connects to the second electrode, wherein the first interlayer dielectric film has a lower polishing rate in the CMP method compared to the second interlayer dielectric film.

The entire disclosure of Japanese Patent Application No. 2007-233877 filed Sep. 10, 2007 is expressly incorporated by reference herein.

### BACKGROUND

1. Technical Field

The present invention relates to methods for manufacturing semiconductor devices, and also relates to methods for manufacturing the same.

2. Related Art

Ferroelectric memory devices (FeRAM) are nonvolatile memory devices capable of low voltage and high speed operations, and their memory cells can be each formed from one transistor and one capacitor (1T/1C). Accordingly, ferroelectric memory devices can achieve integration at the same level of that of DRAM, and are therefore expected as large-capacity nonvolatile memories.

As the structures of such ferroelectric memory devices, a planer type (see, for example, Japanese laid-open patent application JP-A-2003-347512), a stacked type and the like may be enumerated. A ferroelectric memory device in any of the structures described above is equipped with a ferroelectric capacitor having a ferroelectric film placed between a pair of electrodes. One of the electrodes is connected to a wiring, such as, a bit line or the like through a transistor, and the other electrode is connected to another wiring such as a ground line or the like. Generally, these electrodes and wirings are electrically connected through plugs that may be composed of tungsten or the like.

The ferroelectric film described above may be formed from a ferroelectric material having a perovskite type crystal structure represented by a general formula ABO₃, and more specifically, may be composed of lead zirconate titanate (Pb(Zi, Ti)O₃) or the like. The ferroelectric material is an oxide, and therefore needs care so as not to be reduced and thus deteriorated.

To address such necessity, according to the method described in the aforementioned patent document, when forming plugs on ferroelectric capacitors to be connected to the plugs, a titanium nitride film (barrier metal) having hydrogen barrier property is formed inside contact holes in which the plugs are formed in order to prevent the ferroelectric film from being reduced even when the plugs are formed in a reducing atmosphere.

However, in the ferroelectric memory devices, shapes of the contact holes may vary, and therefore differences in the characteristic may occur among the ferroelectric capacitors. More specifically, after forming an interlayer dielectric film to a sufficient thickness, the interlayer dielectric film is polished and thinned by a CMP method or the like to obtain a desired thickness. However, due to differences in the polishing amount which originate from unevenness in the base layer, differences in the thickness appear in the interlayer dielectric film. Therefore, when the interlayer dielectric film is etched, the amount of etching becomes excessively small in thicker portions, and the amount of etching becomes excessively large in thinner portions of the interlayer dielectric film. Consequently, the contact holes, and their bottom portions in particular, are formed in different shapes as being greatly influenced by the amounts of etching.

Such differences in the shape of the bottom portions of the contact holes make it difficult to provide uniform characteristic to the ferroelectric capacitors. For example, when a barrier metal is formed in contact holes, as in the case of the aforementioned patent document, the formed barrier metal may be favorable or defective depending on the shapes of the bottom portions of the contact holes, which causes differences in the functionality of the barrier metal in the contact holes. As a result, the deterioration suppressing effect for the ferroelectric films may vary, causing differences in the characteristic of the ferroelectric capacitors, which results in deterioration in the characteristic of the ferroelectric memory device.

### SUMMARY

In accordance with an advantage of some aspects of the invention, a ferroelectric memory device with excellent characteristic in which differences in the characteristic of ferroelectric capacitors are reduced, and a method for manufacturing the ferroelectric memory device are provided.

In accordance with an embodiment of the invention, a method for manufacturing a semiconductor device includes the steps of: forming a ferroelectric capacitor having a first electrode, a ferroelectric film and a second electrode successively laminated on a base substrate; forming a first interlayer dielectric film that covers the ferroelectric capacitor and the base substrate; forming a material film for a second interlayer dielectric film covering the first interlayer dielectric film; exposing the first interlayer dielectric film located on the ferroelectric capacitor by polishing an upper surface side of the material film for the second interlayer dielectric film by a CMP method; forming a contact hole that penetrates the first interlayer dielectric film and exposes the second electrode, after the step of exposing the first interlayer dielectric film; and forming in the contact hole a plug conductive section that conductively connects to the second electrode, wherein the first interlayer dielectric film has a lower polishing rate in the CMP method compared to the second interlayer dielectric film.

According to the above-described method, the first interlayer dielectric film can be functioned as a polishing stopper in conducting the CMP method in the step of exposing the first interlayer dielectric film, such that the first interlayer dielectric film can be prevented from being excessively polished, and therefore the first interlayer dielectric film can be formed in a desired thickness. Therefore, when a plurality of ferroelectric capacitors are formed in a wafer, as in the case of an ordinary process, the first interlayer dielectric films on the plural ferroelectric capacitors can be formed in a desired thickness, in other words, in a uniform thickness. Accordingly, in the step of forming contact holes, the first interlayer dielectric films formed in a uniform thickness can be uniformly etched, such that the plural connection holes can be formed in a uniform shape. In this manner, differences in the characteristic among the plural ferroelectric capacitors can be reduced, and therefore favorable ferroelectric memory devices with stable characteristic can be manufactured.

The first interlayer dielectric film may preferably be formed from a material having hydrogen barrier property. As a result, in the step of forming a material film for the second interlayer dielectric film and in the steps thereafter, or in state of being used, reducing gas, such as, hydrogen, water vapor and the like can be prevented from penetrating the ferroelectric capacitor from the side of the second interlayer dielectric film or its material film through the first interlayer dielectric film. Therefore, deterioration of the ferroelectric film can be prevented.

The first interlayer dielectric film may be formed from silicon nitride, and the material film for the second interlayer dielectric film may be formed from silicon oxide. In this case, the first interlayer dielectric film may preferably be formed in a thickness between 20 nm and 40 nm.

As a result, the first interlayer dielectric film has a polishing rate in polishing by the CMP method sufficiently lower than that of the second interlayer dielectric film, such that the first interlayer dielectric film can be sufficiently functioned as a stopper against the polishing. Furthermore, when the first interlayer dielectric film is formed in a thickness of 20 nm or greater, a necessary thickness can be left in the first interlayer dielectric film after polishing, when the first interlayer dielectric film is polished and thinned while it is functioning as a stopper. Also, when the first interlayer dielectric film is formed in a thickness of 40 nm or less, differences in the thickness at the time of forming the first interlayer dielectric film can be made sufficiently small. It is noted here that the thickness of the first interlayer dielectric film means the thickness of the first interlayer dielectric film on the ferroelectric capacitor at the time of film formation.

Between the step of forming a contact hole and the step of forming a plug conductive section, the method may preferably include the step of forming a barrier metal with a conductive material having hydrogen barrier property which covers an upper surface of the second electrode exposed inside the contact hole and an inner wall of the contact hole.

As a result, as the plural contact holes are formed in a uniform shape as described above, uniform barrier metals can be formed in all of the contact holes. Etching conditions for forming contact holes in which favorable barrier metals can be formed can be examined in advance, and favorable barrier metals can be formed in all of the plural contact holes formed with such etching conditions. Therefore, deterioration of the ferroelectric films in all of the ferroelectric capacitors can be prevented well, and ferroelectric capacitors with excellent hysteresis characteristic and reduced differences in the characteristic can be formed.

Between the step of forming a ferroelectric capacitor and the step of forming a first interlayer dielectric film, the method may preferably include the step of forming a hydrogen barrier film that covers a side surface and an upper surface of the ferroelectric capacitor.

As a result, in the step of forming a first interlayer dielectric film and in the steps thereafter, or in the state of being used, reducing gas, such as, hydrogen, water vapor and the like can be prevented from penetrating the ferroelectric capacitor from the side of the interlayer dielectric film, and therefore deterioration of the ferroelectric film can be prevented. Also, when the first interlayer dielectric film is formed from a material having hydrogen barrier property, its hydrogen barrier property can be enhanced.

In accordance with an embodiment of the invention, a semiconductor device includes: a ferroelectric capacitor having a first electrode provided on a base substrate, a ferroelectric film provided on the first electrode, and a second electrode provided on the ferroelectric film; a first interlayer dielectric film that covers the ferroelectric capacitor and the base substrate; a second interlayer dielectric film that covers the first interlayer dielectric film except an area above the ferroelectric capacitor; a contact hole that penetrates the first interlayer dielectric film and exposes the second electrode; and a plug conductive section that is formed in the contact hole and conductively connects to the second electrode, wherein the first interlayer dielectric film has a lower polishing rate in a CMP method compared to the second interlayer dielectric film.

As a result, as described above, the first interlayer dielectric films on the plurality of ferroelectric capacitors can be formed in a uniform thickness, such that the plural connection holes can be formed in a uniform shape. In this manner, the characteristic among the plural ferroelectric capacitors becomes uniform, and therefore favorable ferroelectric memory devices with stable characteristic can be provided.

### BRIEF DESCRIPTION OF THE DRAWINGS

FIG. 1 is a side cross-sectional view of the structure of a semiconductor device in accordance with an embodiment of the invention.

FIGS. 2A-2D are schematic views and graphs for describing the shape of a main portion of the semiconductor device.

FIGS. 3A-3D are cross-sectional views schematically showing steps of a method for manufacturing a semiconductor device.

FIGS. 4A-4C are cross-sectional views schematically showing steps of the method for manufacturing a semiconductor device.

FIGS. 5A-5C are cross-sectional views schematically showing steps of the method for manufacturing a semiconductor device.

### DESCRIPTION OF EXEMPLARY EMBODIMENTS

An embodiment of the invention is described below with reference to the accompanying drawings. However, it should be noted that the technical scope of the invention is not limited to the embodiment described below. Also, it should be noted that, although various structures may be exemplified in the following description, using the accompanying drawings, the measurement and scale of each of the components of the structures illustrated in each of the drawings may be appropriately changed with respect to the actual structures so that characteristic features of each of the structures can be readily recognized.

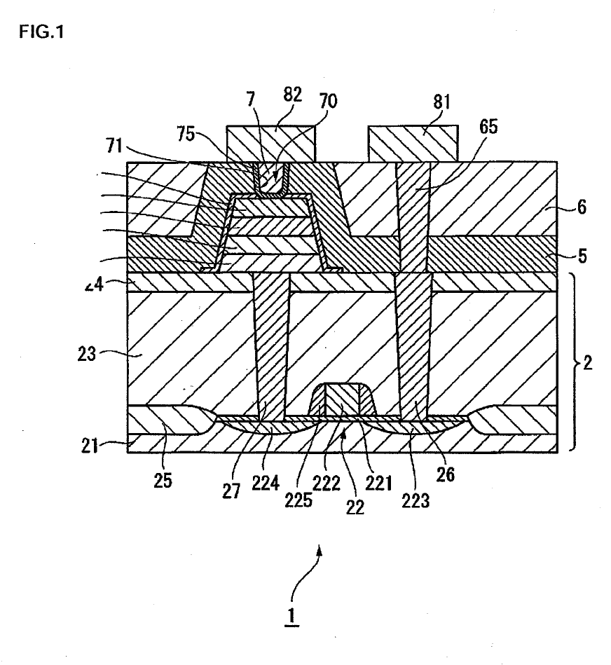

FIG. 1 is a side cross-sectional structural view of a portion of a semiconductor device (ferroelectric memory device) 1 in accordance with an embodiment of the invention. The ferroelectric memory device 1 may be equipped with a plurality of memory cells, but only one of them is illustrated in an enlarged view in FIG. 1. As shown in FIG. 1, the ferroelectric memory device 1 has a stacked type structure, and is equipped with a ferroelectric capacitor 3 provided on a base substrate 2, a first interlayer dielectric film 5 that covers the ferroelectric capacitor 3 and the base substrate 2, and a second interlayer dielectric film 6 that covers the first interlayer dielectric film 5 except a portion thereof above the ferroelectric capacitor 3. Also, in the present embodiment, the semiconductor device is further equipped with a hydrogen barrier film 4 provided between the ferroelectric capacitor 3 and the first interlayer dielectric film 5, a bit line 81 composed of aluminum provided on the first interlayer dielectric film 5, and a ground line 82 composed of aluminum provided on the second interlayer dielectric film 6.

The base substrate 2 includes, for example, a transistor 22 provided on a silicon substrate 21, a first base dielectric film 23 composed of SiO₂ that covers the transistor 22, and a second base dielectric film 24 composed of SiN that covers the first base dielectric film 23. Element isolation regions 25 are provided on a surface layer of the silicon substrate 21, each area between the element isolation regions 25 corresponds to each of the memory cells.

The transistor 22 is formed from a gate dielectric film 221 provided on the silicon substrate 21, a gate electrode 222 provided on the gate dielectric film 221, a source region 223 and a drain region 224 provided on both sides of the gate electrode 222 in the surface layer of the silicon substrate 21, and a side wall 225 provided on a side surface of the gate electrode 222. In the present embodiment, a first plug 26 composed of tungsten is provided on the source region 223 in a manner to be conductively connected to the source region 223, and a second plug 27 composed of tungsten is provided on the drain region 224 in a manner to be conductively connected to the drain region 224. The first plug 26 is electrically connected to a third plug 65 that penetrates the first interlayer dielectric film 5 and the second interlayer dielectric film 6 and is composed of tungsten, and the third plug 65 is electrically connected to the bit line 81. In other words, the source region 223 of the transistor 22 is electrically connected to the bit line 81.

The ferroelectric capacitor 3 is provide on the second plug 27, and is formed from a lower electrode (first electrode) 32, a ferroelectric film 33 and an upper electrode (second electrode) 34. Further, in the present embodiment, a base conductive section 31 composed of TiAlN is provided between the second plug 27 and the ferroelectric capacitor 3.

In the present embodiment, the lower electrode 32 is formed from an iridium (Ir) film, an iridium oxide (IrOx) film and a platinum (Pt) film sequentially laminated on the base conductive section 31, and is electrically connected to the drain region 224 through the base conductive section 31 and the second plug 27.

The ferroelectric film 33 is provided on the lower electrode 32 and is formed from a ferroelectric material. Typical ferroelectric materials include materials having a perovskite crystal structure that may be expressed by a general formula ABO₃, more specifically, for example, PZT (Pb(Zr, Ti))O₃), PLZT ((Pb, La)(Zr, Ti)O₃) and the like, or ferroelectric materials in which metal, such as, niobate (Nb) or the like is added to the foregoing materials. As the ferroelectric material in the present embodiment, PZT is used.

The upper electrode 34 is formed from a Pt film, an IrOx film and an Ir film sequentially provided on the ferroelectric film 33, and is electrically connected to a fourth plug (plug conductive section) 7 to be described below.

In this manner, each of the upper electrode 34 and the lower electrode 32 may be formed from a laminate of multiple films composed of mutually different materials. As a result, functionalities can be given to the upper electrode 34 and the lower electrode 32. For example, a function to increase adhesion between the ferroelectric film 33 and the upper electrode 34 and/or between the ferroelectric film 33 and the lower electrode 32, a function as an oxygen barrier film or a hydrogen barrier film, a function to improve the crystal orientation property of the ferroelectric film 33 and the like may conceivably be given.

The hydrogen barrier film 4 is formed from a dielectric material having hydrogen barrier property, and for example, aluminum oxide (Al Ox) is used as the material for the hydrogen barrier film 4 in the present embodiment. The ferroelectric film 33 of the ferroelectric capacitor 3 is formed from oxide material, as described above, such that the ferroelectric film 3 is reduced and deteriorated when exposed to reducing gas such as hydrogen gas. But the deterioration can be prevented by covering the ferroelectric capacitor 3 with the hydrogen barrier film 4.

The second interlayer dielectric film 6 may be formed from, for example, SiO₂. Also, the first interlayer dielectric film 5 is formed from a dielectric material that has a lower polishing rate in a CMP method than that of the second interlayer dielectric film 6, and therefore can function as a stopper in polishing by the CMP method. In order to function as a stopper, the first interlayer dielectric film 5 may preferably have a polishing rate that is ⅕ or less of the polishing rate of the second interlayer dielectric film 6, and more preferably 1/10 or less thereof. Also, the first interlayer dielectric film 5 may preferably be formed from a material having hydrogen barrier property, such that reducing gas can be prevented from penetrating the ferroelectric capacitor 3 from the side of the second interlayer dielectric film 6. As specific examples of materials for the first interlayer dielectric film 5, silicon nitrides, such as, SiN, SiON and the like may be enumerated, and SiN may be particularly favorable.

A contact hole 70 that penetrates the first interlayer dielectric film 5 and the hydrogen barrier film 4 and exposes the upper electrode 34 of the ferroelectric capacitor 3 is formed over the ferroelectric capacitor 3. The contact hole 70 has a circular opening shape, and its interior is provided with a barrier metal 75 that covers an upper surface of the upper electrode 34 exposed in the contact hole 70 and an inner wall surface of the contact hole 70. Also, a fourth plug (plug conductive section) 7 is embedded inside the barrier metal 75 in the contact hole 79. The fourth plug 7 is formed from tungsten in the present embodiment, and is conductively connected to the upper electrode 34 through the barrier metal 75, and electrically connected to the ground line 82. In other words, the upper electrode 34 of the ferroelectric capacitor 3 is electrically connected to the ground line 82 through the barrier metal 75 and the fourth plug 7.

The barrier metal 75 is formed from a conductive material having hydrogen barrier property, and a portion thereof that covers the top surface of the upper electrode 34 can prevent reducing gas from penetrating the ferroelectric capacitor 3 from the side of the contact hole 70. Also, a portion of the barrier metal 75 that covers the inner wall surface 71 inside the contact hole 70 is capable of increasing the adhesion between the fourth plug 7 and the inner wall surface 71 of the contact hole 70. In the present embodiment, the barrier metal 75 has a two-layer structure in which a Ti film (not shown) and a TiN film (not shown) are sequentially laminated. Also, because the inner wall surface 71 of the contact hole 70 near the upper electrode 34 is well shaped, as described below, in other words, the inner wall surface of the hydrogen barrier film 4 in the opening section is well shaped in accordance with the present embodiment, the coverage of material for the barrier metal 75 is improved, and therefore the barrier metal 75 can be formed without weak points. The shape of the inner wall surface of the hydrogen barrier film 4 is described below in detail.

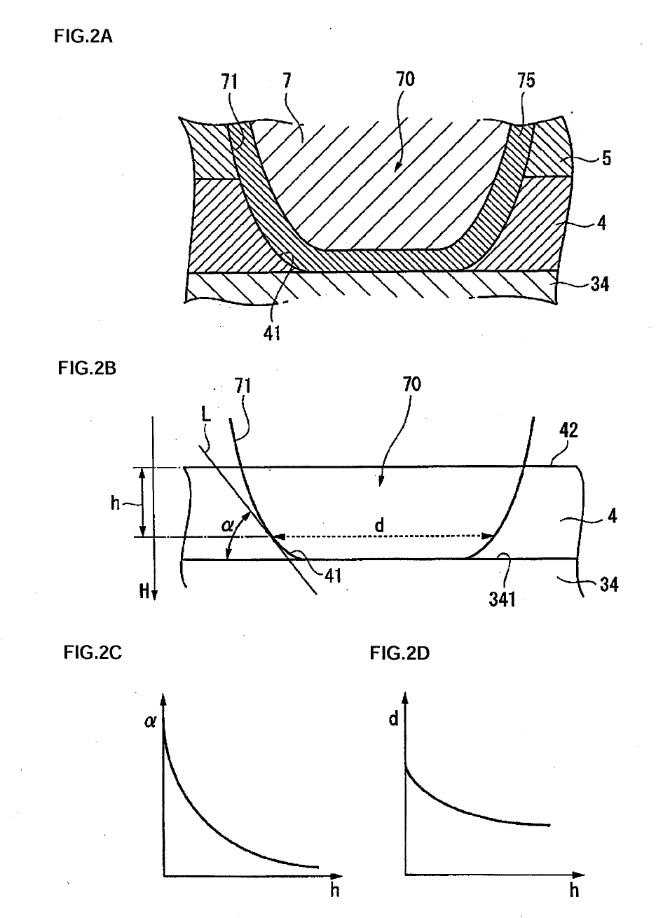

FIG. 2A is an enlarged cross-sectional view of a portion of the contact hole 70 near its bottom surface, and FIG. 2B is a schematic diagram for describing several parameters concerning the configuration representation of the inner wall surface 41. Also, FIGS. 2C and 2D are graphs showing the relations among the parameters in the shape of the inner wall surface 41.

As shown in FIG. 2A, the inner wall surface 41 of the hydrogen barrier film 4 includes a curved surface that defines a concave opening toward the inner side of the contact hole 70. Also, the inner diameter (inner dimension) of the contact hole 70 reduces in diameter (reduces in dimension) toward the upper electrode 34. More specifically, the shape of the inner wall surface 41 of the hydrogen barrier film 4 can be expressed by using the parameters as follows.

As shown in FIG. 2B, a distance from the upper surface 42 of the hydrogen barrier film 4 in a depth direction H of the contact hole 70 is defined as a depth h. A tangential line that contacts the inner wall surface 41 of the hydrogen barrier film 4 at the depth h in the hydrogen barrier film 4 is defined as a tangential line L. An acute angle among angles of the tangential line L with respect to the upper surface 341 of the upper electrode 34 is defined as an angle α. A dimension of the contact hole 70 at the depth h in a direction orthogonal to the depth direction H is defined as an inner diameter d. With the parameters set as described above, it is observed that the angle a decreases monotonically with increasing depth h, as shown in FIG. 2C, and the inner diameter d decreases monotonically with increasing depth h, as shown in FIG. 2D.

With the structure described above, upon application of a voltage to the gate electrode 222 of the transistor 22, an electrical field is applied between the source region 223 and the drain region 224 thereby turning on the channel, wherein an electrical current can be circulated. When the channel is turned on, an electrical signal from the bit line 81 electrically connected to the source region 223 is transmitted to the drain region 224, and then transmitted to the lower electrode 32 of the ferroelectric capacitor 3 electrically connected to the drain electrode 224. Thus, a voltage can be applied between the upper electrode 34 and the lower electrode 32 of the ferroelectric capacitor 3, whereby a charge (data) can be accumulated in the ferroelectric film 33. In this manner, an electrical signal to the ferroelectric capacitor 3 can be switched by the transistor 22, whereby data (charge) can be read from or written in the ferroelectric memory device 1.

Next, a method for manufacturing a semiconductor device in accordance with an embodiment of the invention is described, using a method for manufacturing the ferroelectric memory device 1 as an example.

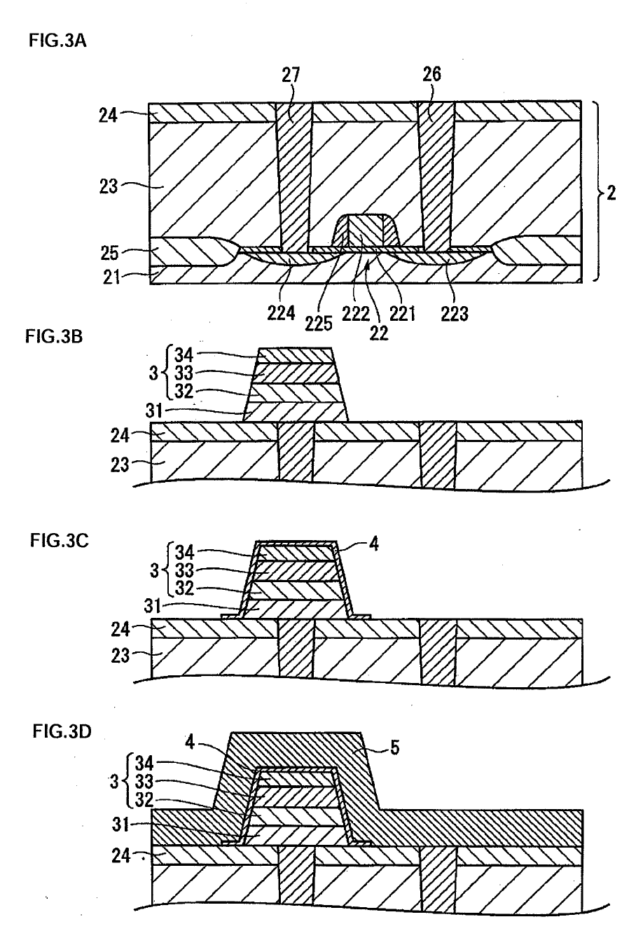

FIGS. 3A-3D, FIGS. 4A-4C, and FIGS. 5A-5C are cross-sectional views showing steps of a method for manufacturing the ferroelectric memory device 1 in accordance with the present embodiment. It is noted that, according to the manufacturing method of the present embodiment, a plurality of memory cells are formed in a silicon wafer (silicon substrate 21). However, the figures used for the description below show only a main portion of the ferroelectric memory device.

First, as shown in FIG. 3A, a base substrate 2 is formed by using a known method. More specifically, for example, element isolation regions 25 are formed in a silicon substrate 21 by a LOCOS method, a STI method or the like, and a gate dielectric film 221 is formed on the silicon substrate 21 between the element isolation regions 25 by a thermal oxidation method or the like. Then, a gate electrode 222 composed of polycrystal silicon or the like is formed on the gate dielectric film 221. Then, doped regions 223 and 224 are formed by implanting impurities in the surface layer of the silicon substrate 21 between the element isolation regions 25 and the gate electrode 222. Then, an etching back method or the like is used to form a side wall 225. In accordance with the present embodiment, the doped region 223 may be functioned as a source region, and the doped region 224 may be functioned as a drain region.

Then, a film of SiO₂ is formed by, for example, a CVD method to form a first base dielectric film 23 on the silicon substrate 21 where the transistor 22 is formed, and then a film of SiN is formed by, for example, a CVD method to form a second base dielectric film 24 on the first base dielectric film 23. Then, the first base dielectric film 23 and the second base dielectric film 24 over the source region 223 and the drain region 224 are etched, thereby forming a through hole that exposes the source region 223 and a through hole that exposes the drain region 224. Then, for example, films of Ti and TiN are sequentially formed by a sputter method in the through holes, respectively, thereby forming adhesion layers (not shown).

Then, a film of tungsten is formed by, for example, a CVD method over the entire surface of the second base dielectric film 24 including portions inside the through holes thereby embedding tungsten inside the through holes. Then, the tungsten over the second base dielectric film 24 is polished by a CMP method or the like, thereby removing the tungsten on the second base dielectric film 24. As a result, a first plug 26 and a second plug 27 are embedded in the through holes, respectively. The second base dielectric film 24 composed of SiN has a lower polishing rate in a CMP method than that of the first base dielectric film 23 composed of SiO₂, such that portions above the first base dielectric film 23 can be prevented from being excessively polished by the CMP method.

Next, as shown in FIG. 3B, a base conductive section 31 and a ferroelectric capacitor 3 are formed on the second base dielectric film 24 of the base substrate 2. More specifically, first, a layer of material for a base conductive section 31, such as, for example, titanium aluminum nitride (TiAlN) is formed on the second base dielectric film 24 by a sputter method. Then, as materials for a lower electrode 32, for example, iridium (Ir), iridium oxide (IrOx), and platinum (Pt) films are sequentially formed on the layer for the base conductive section 31 by a sputter method. Then, as a material for a ferroelectric film 33, for example, a layer of lead zirconate titanate (Pb(Zi, Ti)O₃: PZT) is formed on the layer for the lower electrode layer by a sol-gel method, a sputter method, a MOCVD method or the like. Then, as a material for an upper electrode 34, for example, Pt, IrOx and Ir films are sequentially formed on the layer for the ferroelectric film 33 by a sputter method.

Then, a resist pattern (not shown) is formed on the upper surface of the material films, in other words, on the film that becomes the upper electrode 34 by, for example, known resist technique and photolithography method. By using the resist pattern as a mask, the material films are etched, thereby forming the base conductive section 31, and the ferroelectric capacitor 3 having the lower electrode 32, the ferroelectric film 33 and the upper electrode 34 sequentially laminated on the base conductive section 31.

Next, a material film for a hydrogen barrier film 4, for example, AlOx is formed by a sputter method on the entire top surface of the second base dielectric film 24 including the ferroelectric capacitor 3. Then, the AlOx film is patterned by using known resist technique and etching technique, thereby forming the hydrogen barrier film 4 that covers the top surface and the side surface of the ferroelectric capacitor 3, as well as the side surface of the base conductive section 31 and the second base dielectric film 24 around the ferroelectric capacitor 3 in accordance with the present embodiment, as shown in FIG. 3C. It is noted that the AlOx film may be formed by a method that combines a sputter method and a CVD method.

Next, as shown in FIG. 3D, a layer of SiN is formed to a thickness of about 20-40 nm (i.e., about 2000 Å-4000 Å) by, for example, a CVD method, in a manner to cover the hydrogen barrier film 4 and the second base dielectric film 24 of the base substrate 2, thereby forming a first interlayer dielectric film 5. It is known that a film in uniform thickness can be formed by a CVD method. In the present embodiment, the first interlayer dielectric film 5 is also formed in uniform film thickness on the ferroelectric capacitor 3.

In accordance with the present embodiment, prior to forming the first interlayer dielectric film 5, the hydrogen barrier film 4 that covers the top surface and side surface of the ferroelectric capacitor 3 is formed. Therefore, even when the first interlayer dielectric film 5 is formed in a reducing atmosphere, the ferroelectric capacitor 3 is not exposed to the reducing atmosphere, and therefore can be prevented from deterioration. Also, because SiN is a material having hydrogen barrier property, the hydrogen barrier property of the hydrogen barrier film 4 can be reinforced by forming the first interlayer dielectric film 5 from SiN.

Alternatively, the first interlayer dielectric film 5 may be formed without forming the hydrogen barrier film 4. For example, a film of SiN that covers the top surface and side surface of the ferroelectric capacitor 3 may be formed in a non-reducing atmosphere by, for example, a sputter method, and then, a film of SiN that covers the SiN film and the second base dielectric film 24 may be formed by a CVD method like the present embodiment, thereby forming a first interlayer dielectric film 5 composed of the SiN film formed by the sputter method and the SiN film formed by the CVD method.

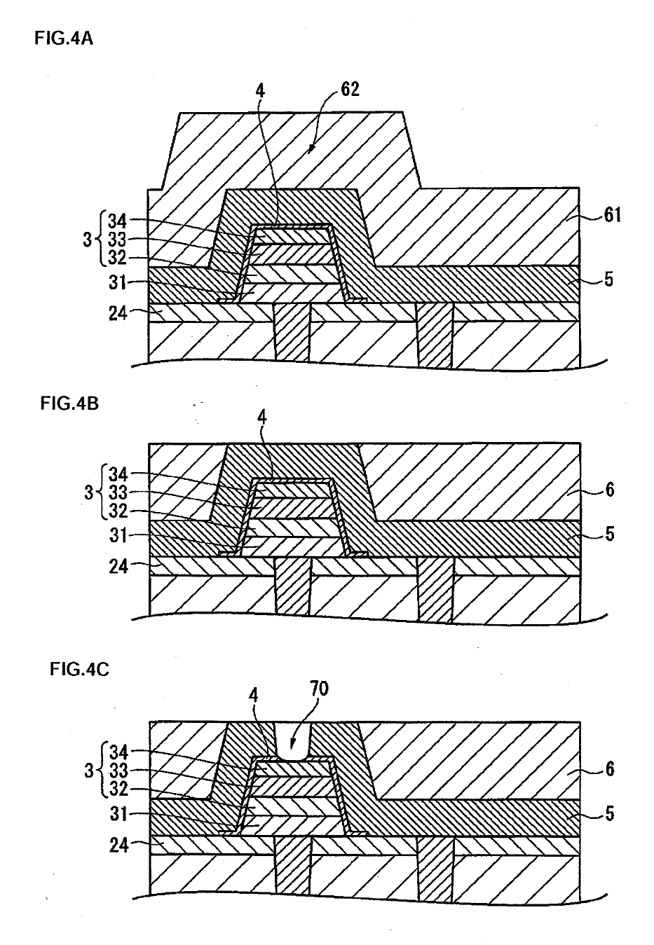

Next, as shown in FIG. 4A, a film of SiO₂ that covers the first interlayer dielectric film 5 is formed to a thickness of about 60-100 nm (i.e., about 6000 Å-10000 Å), thereby forming a material film 61 for a second interlayer dielectric film 6. As described above, in accordance with the present embodiment, the hydrogen barrier film 4 is formed, and the first interlayer dielectric film 5 is formed from SiN, such that its hydrogen barrier property is reinforced. Therefore, reducing gases such as water vapor, hydrogen gas and the like that may be generated when forming the material film 61 for the second interlayer dielectric film 6 can be prevented from penetrating the ferroelectric capacitor 3 or deteriorating the ferroelectric film 33. It is noted that, like the first interlayer dielectric film 5, the material film 61 for the second interlayer dielectric film 6 is also formed in generally uniform film thickness on the second base dielectric film 24, such that the material film 61 for the second interlayer dielectric film 6 forms an upheaval 62 on the ferroelectric capacitor 3.

Next, as shown in FIG. 4B, a top surface side of the material film 61 for the second interlayer dielectric film 6 is polished and thinned by a CMP method, thereby exposing the first interlayer dielectric film 5 on the ferroelectric capacitor 3. As described above, in the manufacturing method in accordance with the present embodiment, a plurality of ferroelectric capacitors 3 are formed in a silicon wafer, and the polishing rate in polishing by a CMP method varies in a plane on the silicon wafer.

More specifically, as the upheavals 62 are generated over the ferroelectric capacitors 3, the upheavals 62 are densely distributed in a region where the ferroelectric capacitors 3 are densely arranged, and the upheavals 62 are sparsely distributed in a region where the ferroelectric capacitors 3 are sparsely arranged. Consequently, when the top surface side of the material film 61 for the second interlayer dielectric film 6 is polished, in other words, when the upheavals 62 are polished, the polishing rate is lower in the region where the ferroelectric capacitors 3 are densely arranged, like in the center area of the silicon wafer, than in the region where they are sparsely arranged, like in the peripheral area of the silicon wafer.

Therefore, by the conventional methods, it was difficult to form an interlayer dielectric film over a ferroelectric capacitor in a uniform thickness.

However, according to the method of the invention, the first interlayer dielectric film 5 is formed from a material with a lower polishing rate (SiN in the present embodiment) in polishing by the CMP method than that of the material film 61 for the second interlayer dielectric film 6 (SiO₂ in the present embodiment). Therefore, the thickness of the first interlayer dielectric film 5 over the ferroelectric capacitors 3 can be made uniform.

More specifically, by polishing with certain polishing conditions such as the polishing time set for exposing the first interlayer dielectric film 5 in the area where the ferroelectric capacitors 3 are densely arranged (hereafter referred to as a densely arranged area), the first interlayer dielectric film 5 in the area where the ferroelectric capacitors 3 are scarcely arranged (hereafter referred to as a scarcely arranged area) is exposed earlier than in the densely arranged area, and the first interlayer dielectric film 5 in the scarcely arranged area may be excessively polished. However, the polishing rate of the first interlayer dielectric film 5 is considerably lower than that of the material film 61 for the second interlayer dielectric film 6, such that the reduction in the film of the first interlayer dielectric film 5 caused by the excessive polishing becomes extremely small. In this manner, differences in the thickness of the second interlayer dielectric film 6 can be absorbed by the first interlayer dielectric film 5, and the thickness of the first interlayer dielectric film 5 can be made generally the same among the areas where the ferroelectric capacitors 3 are densely arranged and scarcely arranged. It is noted that the material film 61 for the second interlayer dielectric film 6 is formed thicker than the first interlayer dielectric film 5, and therefore relatively large variations in the thickness are generated, for example, between the peripheral area and the central area of the silicon wafer, due to the applied film forming method. However, the variations in the thickness can also be absorbed by the first interlayer dielectric film 5, and the thickness of the interlayer dielectric film 5 can be made generally uniform on the silicon wafer.

Next, as shown in FIG. 4C, a contact hole 70 that penetrates the first interlayer dielectric film 5 and the hydrogen barrier film 4 on the ferroelectric capacitor 3 and exposes the upper electrode 34 of the ferroelectric capacitor 3 is formed. More specifically, a resist pattern (not shown) is formed on the first interlayer dielectric film 5 by using, for example, known resist technique and photolithography method at a position corresponding to the ferroelectric capacitor 3. By using the resist pattern as a mask, the first interlayer dielectric film 5 and the hydrogen barrier film 4 are etched together or independently, thereby forming the contact hole 70.

The first interlayer dielectric film 5 has a uniform thickness, as described above, and thus can be uniformly etched, such that the contact holes 70 can be formed in uniform shape. In accordance with the present embodiment, etching conditions for forming the contact holes 70 in favorable shape are examined in advance, and the etching is conducted with such etching conditions, whereby the contact holes 70 with favorable shape are formed over the plural ferroelectric capacitors 3, respectively.

It is noted that the favorable shape of the contact hole 70 refers to a shape in which, as shown in FIG. 2A, the inner wall surface 71 of the contact hole 70 on the side of the upper electrode 34, at the inner wall surface 41 in the opening section of the hydrogen barrier film 4 in accordance with the present embodiment, has a curved concave surface that is open toward the inner side of the contact hole 70, and the inner diameter of the contact hole 70 gradually reduces toward the upper electrode 34.

According to the conventional method, as the interlayer dielectric film includes differences in thickness, the bottom portions of the contact holes may be formed with differences in shape, some formed favorably and the other defectively. For example, the etching amount becomes excessively large in areas where the interlayer dielectric film over the ferroelectric capacitor is relatively thin, and the contact hole near its bottom surface, in other words, near the upper electrode of the ferroelectric capacitor, is formed with an inner wall surface that is bluff with respect to the top surface of the upper electrode. On the other hand, the etching amount becomes excessively small in areas where the interlayer dielectric film over the ferroelectric capacitor is relatively thick, and the inner wall surface of the contact hole has a stepped configuration that protrudes toward the interior of the contact hole. Accordingly, in either of the cases of the etching amount being excessively large or excessively small, it is difficult to form a favorable barrier metal in the contact hole.

Next, as shown in FIG. 6A, a barrier metal 75 is formed with a conductive material having hydrogen barrier property that covers the top surface of the upper electrode 34 exposed in the contact hole 70 and the inner wall surface 71 of the contact hole 70. In accordance with the present embodiment, films of Ti and TiN are sequentially formed by a sputter method, thereby forming the barrier metal 75 in a two-layer structure composed of the Ti film and the TiN film. As the contact hole 70 is formed in a favorable shape, as described above, and does not have a bluff step difference between the top surface of the upper electrode 34 and the inner wall surface 71 of the contact hole 70, such that the coverage property of the material for the barrier metal 75 shall not be damaged. Accordingly, the barrier metal 75 can be formed favorably without generating weak points such as locally thinned portions, portions with cracks and the like.

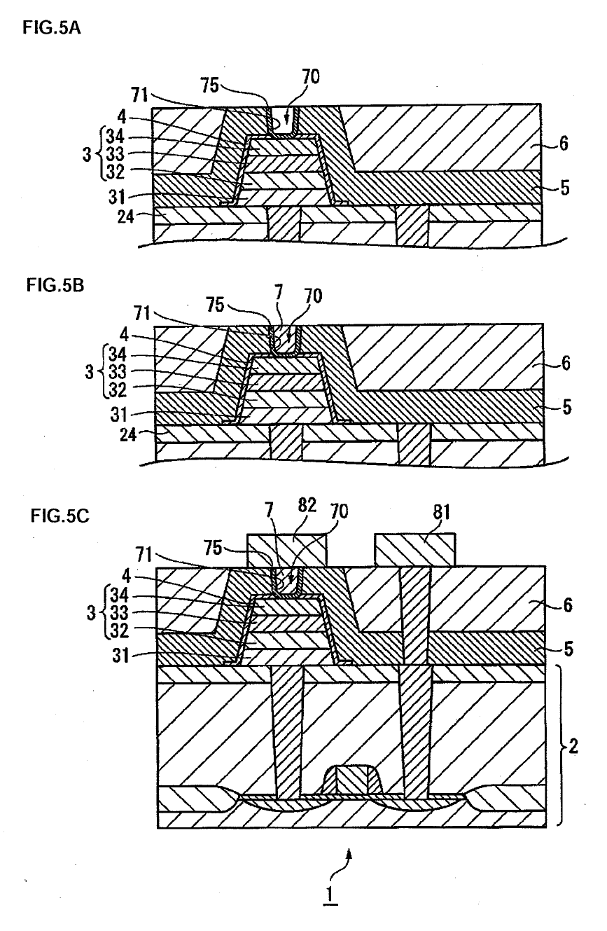

Next, as shown in FIG. 5B, a fourth plug (plug conductive section) 7 that conductively connects to the barrier metal 75 is embedded in the contact hole 70. More specifically, for example, tungsten is deposited in a film by a CVD method on the entire surface of the interlayer dielectric film 6 including inside the contact hole 70, thereby embedding the tungsten inside the contact hole 70. Then, by polishing portions over the interlayer dielectric film 6 by a CMP method or the like, the tungsten on the interlayer dielectric film 6 is removed, and the fourth plug 7 is embedded in the contact hole 70.

Generally, the films are formed in a reducing atmosphere according to the CVD method. However, in accordance with the present embodiment, the barrier metal 75 having hydrogen barrier property that covers the upper electrode 34 is formed, and weak points are not generated in the barrier metal 75. Therefore, the reducing gas, such as, water vapor, hydrogen gas and the like cannot penetrate the ferroelectric capacitor 3 through weak points, and the ferroelectric film 33 can be prevented from being reduced or deteriorated.

Next, a through hole that penetrates the first interlayer dielectric film 5 and the second interlayer dielectric film 6 and exposes the first plug 26 is formed. Then, films of Ti and TiN are sequentially formed by a sputter method in the through hole, thereby forming an adhesion layer (not shown). Then, tungsten is formed in a film by, for example, a CVD method on the entire top surface of the interlayer dielectric film 6 including inside the through hole, thereby embedding the tungsten inside the through hole. Portions of the tungsten over the interlayer dielectric film 6 are polished by a CMP method or the like, whereby the tungsten on the interlayer dielectric film 6 is removed, leaving a third plug 65 conductively connected to the first plug 26 embedded inside the through hole.

Then, a film of aluminum that covers the first interlayer dielectric film 5 and the second interlayer dielectric film 6 is formed by, for example, a sputter method, and the film is patterned by known resist technique and etching technique, thereby forming a bit line 81 conductively connected to the third plug 65 and a ground line 82 conductively connected to the fourth plug 7. In this manner, the ferroelectric memory device 1 can be manufactured.

According to the method for manufacturing a semiconductor device in accordance with the embodiment of the invention described above, the first interlayer dielectric film 5 is used to function as a stopper, the first interlayer dielectric film 5 on the plural ferroelectric capacitors 3 can be formed in a uniform thickness, and contact holes 70 can be uniformly formed. Accordingly, for example, the barrier metal 75 can be formed uniformly within the respective contact holes 70, and thus the barrier metal 75 can uniformly exhibit the hydrogen barrier property on the respective ferroelectric capacitors 3, whereby ferroelectric capacitors 3 having uniform characteristics can be formed. Therefore, an excellent-quality ferroelectric memory device (semiconductor device) 1 with stable characteristics, equipped with the ferroelectric capacitors 3 with uniform characteristics, can be manufactured.

Also, the ferroelectric memory device (semiconductor device) 1 that is obtained by the manufacturing method in accordance with the present embodiment of the invention has reduced differences in the characteristics of the ferroelectric capacitors, and thus has stable, excellent characteristics.

Also, in accordance with the present embodiment, the contact hole 70 is formed in a shape that provides good coverage property of material for the barrier metal 75. Therefore, even when the fourth plug 7 is formed in a reducing atmosphere, the ferroelectric film 33 of the ferroelectric capacitor 3 would not be deteriorated, such that the ferroelectric capacitor with excellent hysteresis characteristic can be formed. Also, by forming the second base dielectric film 24 and the first interlayer dielectric film 5 from the same material (SiN in the present embodiment), adhesion between these films can be made excellent, such that, for example, the hydrogen barrier film 4 can be prevented from peeling off the second base dielectric film 24 and the ferroelectric capacitor 3.

Moreover, although the present embodiment is applied to a stacked type ferroelectric memory device 1, the embodiment may be applied to a planer type or the like. Also, the invention is applicable to structures different from the one describe above. For example, the invention is applicable to a structure in which the bit line 81 and the ground line 82 are interchanged such that the upper electrode 34 of the ferroelectric capacitor 3 is conductively connected to the bit line, a structure with other wiring structures, such as, multilayer wirings, and the like.

Furthermore, in accordance with the present embodiment, the hydrogen barrier film 4 is formed, and the inner wall surface 71 of the contact hole 70 at the hydrogen barrier film 4, in other words, the inner wall surface 41 of the hydrogen barrier film 4 at the opening section is formed in a favorable shape. However, when the hydrogen barrier film 4 is not formed, the first interlayer dielectric film 5 on the side of the upper electrode 34 can be formed in a favorable shape, thereby forming a favorable barrier metal.

What is claimed is:

1. A method for manufacturing a semiconductor device, the method comprising the steps of:
forming a ferroelectric capacitor having a first electrode, a ferroelectric film and a second electrode successively laminated on a base substrate;
forming a first interlayer dielectric film that covers the ferroelectric capacitor and the base substrate;
forming a material film for a second interlayer dielectric film covering the first interlayer dielectric film;
exposing the first interlayer dielectric film located on the ferroelectric capacitor by polishing an upper surface side of the material film for the second interlayer dielectric film by a CMP method;
forming a contact hole that penetrates the first interlayer dielectric film and exposes the second electrode, after the step of exposing the first interlayer dielectric film; and
forming in the contact hole a plug conductive section that conductively connects to the second electrode,
wherein the first interlayer dielectric film has a lower polishing rate in the CMP method compared to the second interlayer dielectric film.

2. A method for manufacturing a semiconductor device according to claim 1, wherein the first interlayer dielectric film is formed from a material having hydrogen barrier property.

3. A method for manufacturing a semiconductor device according to claim 1, wherein the first interlayer dielectric film is formed from silicon nitride, and the material film for the second interlayer dielectric film is formed from silicon oxide.

4. A method for manufacturing a semiconductor device according to claim 3, wherein the first interlayer dielectric film is formed in a thickness between 20 nm and 40 nm.

5. A method for manufacturing a semiconductor device according to claim 1, further comprising, between the step of forming a contact hole and the step of forming a plug conductive section, the step of forming a barrier metal from a conductive material having hydrogen barrier property which covers a top surface of the second electrode exposed inside the contact hole and an inner wall of the contact hole.

6. A method for manufacturing a semiconductor device according to claim 1, further comprising, between the step of forming a ferroelectric capacitor and the step of forming a first interlayer dielectric film, the step of forming a hydrogen barrier film that covers a side surface and a top surface of the ferroelectric capacitor.

7. A semiconductor device comprising:
a ferroelectric capacitor having a first electrode provided on a base substrate, a ferroelectric film provided on the first electrode, and a second electrode provided on the ferroelectric film;
a first interlayer dielectric film that covers the ferroelectric capacitor and the base substrate;
a second interlayer dielectric film that covers the first interlayer dielectric film except an area above the ferroelectric capacitor;
a contact hole that penetrates the first interlayer dielectric film and exposes the second electrode; and
a plug conductive section that is formed in the contact hole and conductively connects to the second electrode,
wherein the first interlayer dielectric film has a lower polishing rate in a CMP method compared to the second interlayer dielectric film.
